(19) United States
(12) Patent Application Publication
(10) Pub. No.: US 2026/0190900 A1
(43) Pub. Date: Jul. 2, 2026

(54) SUBSTRATE PROCESSING APPARATUS

(71) Applicant: SEMES CO., LTD., Cheonan-si (KR)

(72) Inventors: Eun Seok KIM, Asan-si (KR); Ki Bong KIM, Paju-si (KR)

(73) Assignee: SEMES CO., LTD., Cheonan-si (KR)

(21) Appl. No.: 19/436,149

(22) Filed: Dec. 30, 2025

(30) Foreign Application Priority Data
Dec. 30, 2024 (KR) 10-2024-0200491

(51) Int. Cl. H10P 72/00

(52) U.S. Cl. CPC H10P 72/0408; H10P 72/0616

(57) ABSTRACT

Provided is an apparatus for processing a substrate. The apparatus includes: a housing; a support unit a fluid pipe in which a supercritical fluid flows; a main valve installed in the fluid pipe and opening and closing a passage through which the fluid flows in the fluid pipe; an emergency valve installed in the fluid pipe and opening and closing a passage through which the fluid flows in the fluid pipe; and a controller for controlling the main valve and the emergency valve. The controller controls the flow of the fluid in the fluid pipe by operating the main valve when the main valve is in a normal state, and controls the flow of fluid in the fluid pipe by operating the emergency valve when the main valve is in an abnormal state.

### CROSS-REFERENCE TO RELATED APPLICATION

This application claims priority to and the benefit of Korean Patent Application No. 10-2024-0200491 filed in the Korean Intellectual Property Office on Dec. 30, 2024, the entire contents of which are incorporated herein by reference.

### TECHNICAL FIELD

The present invention relates to an apparatus for processing a substrate, and more particularly, to a substrate processing apparatus for pulse-supplying a fluid by opening and closing a valve.

### BACKGROUND ART

Semiconductor devices are manufactured through various processes including a deposition process, a photolithography process, and an etching process of forming a circuit pattern on a substrate, such as a silicon wafer. During this manufacturing process, various foreign substances, such as particles, organic contaminants, and metal impurities, remain on the wafer. Since these foreign substances cause defects in the substrate, they act as a factor that directly affects the yield of the semiconductor device. Therefore, in the semiconductor manufacturing process, a cleaning process for removing such foreign substances is essentially accompanied.

In general, the cleaning process includes chemical liquid treatment, rinsing treatment, and drying treatment. Recently, in order to prevent the pattern on the substrate from collapsing during the rinsing treatment, drying treatment is performed using a supercritical fluid.

The drying treatment is performed in a drying chamber. In order to perform the drying treatment, the substrate is first loaded into the drying chamber, and the treatment space is pressurized by supplying the supercritical fluid to the treatment space inside the drying chamber in the state where the substrate is loaded in, the substrate is dried using the supercritical fluid, and when the drying of the substrate is completed, the treatment space is depressurized and the substrate is unloaded from the treatment space. During the drying of the substrate, the supercritical fluid is supplied to the treatment space in a pulse manner in which the supply and discharge of the supercritical fluid are repeated.

The pulse type supply and discharge are performed by repeated opening and closing of valves installed in the fluid pipe. In the case of a fluid pipe connected to the drying chamber using a general supercritical fluid, the pulse process depends on one valve. During this pulse process, a load is easily applied according to repeated use of the valve, which causes a valve failure.

In general, the valve opens and closes the flow of the fluid in the valve by ascending and descending of the diaphragm. However, leakage occurs even when the valve is closed as the diaphragm is worn due to repetition of ascending and descending. In this case, it is necessary to replace the valve on the pipe, and since the use of the apparatus is stopped during the replacement, the operation rate of the apparatus is greatly reduced.

### SUMMARY OF THE INVENTION

The present invention has been made in an effort to provide a substrate processing apparatus for preventing a decrease in an operation rate of an apparatus due to a failure of a valve.

The present invention has also been made in an effort to provide a substrate processing apparatus capable of extending a replacement cycle of a valve.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a housing having a treatment space for processing a substrate; a support unit for supporting the substrate in the treatment space; a fluid pipe which communicates with the treatment space and in which a fluid flows; a main valve installed in the fluid pipe and opening and closing a passage through which the fluid flows in the fluid pipe; an emergency valve installed in the fluid pipe and opening and closing the passage through which the fluid flows in the fluid pipe; and a controller configured to control the main valve and the emergency valve, wherein when the main valve is in a normal state, the controller controls the flow of fluid in the fluid pipe by operating the main valve between the main valve and the emergency valve, and when the main valve is in an abnormal state, the controller may controls the flow of fluid in the fluid pipe by operating the emergency valve between the main valve and the emergency valve.

According to the exemplary embodiment of the present invention, wherein the fluid pipe includes: a first pipe in which the main valve is installed; and a second pipe in which the emergency valve is installed, and the second pipe is branched from the first pipe at a first point that is upstream from the main valve and may joins the first pipe at a second point that is downstream from the main valve.

According to the exemplary embodiment of the present invention, wherein each of the main valve and the emergency valve may be a normal close valve.

According to the exemplary embodiment of the present invention, wherein while the fluid pipe is controlled to be opened and closed by any one of the main valve and the emergency valve, the other valve may be maintained in a closed state.

According to the exemplary embodiment of the present invention, wherein the main valve and the emergency valve may be arranged in series with each other.

According to the exemplary embodiment of the present invention, wherein each of the main valve and the emergency valve may be a normal open valve.

According to the exemplary embodiment of the present invention, wherein while the fluid pipe is controlled to be opened and closed by any one of the main valve or the emergency valve, the other valve may be maintained in an open state.

According to the exemplary embodiment of the present invention, wherein whether the main valve is in a normal state may be determined based on whether a leak occurs in a pipe to which a driving pressure for driving the main valve is provided, whether a leak occurs in the main valve, or whether a leak occurs in the supply pipe.

According to the exemplary embodiment of the present invention, wherein the fluid pipe may be a supply pipe that supplies a fluid to the treatment space.

According to the exemplary embodiment of the present invention, wherein the fluid pipe may be a discharge pipe that discharges a fluid from the treatment space.

According to the exemplary embodiment of the present invention, further comprising: a reservoir in which a fluid is stored, wherein the fluid pipe includes: a supply pipe for supplying a fluid to the treatment space; and a discharge pipe for discharging a fluid from the treatment space, the supply pipeincludes: an upstream supply pipe connected to the reservoir; a first downstream supply pipe branched from the upstream supply pipe and connected to the housing; and a second downstream supply pipe branched from the upstream supply pipe and connected to the housing, and both the main valve and the emergency valve may be installed only in the first downstream supply pipe between the first downstream supply pipe and the second downstream supply pipe.

According to the exemplary embodiment of the present invention, wherein the main valve and the emergency valve have the same structure.

According to the exemplary embodiment of the present invention, wherein the controller controls the apparatus to sequentially perform: a loading operation of loading the substrate into the treatment space; after the loading operation, a pressurizing operation of pressurizing the treatment space by supplying the fluid to the treatment space; after the pressurizing operation, a pulse processing operation of pulse-supplying the fluid into the treatment space to process the substrate in the treatment space; a depressurizing operation of depressurizing the treatment space by discharging the fluid from the treatment space; and a discharging operation of discharging the substrate from the treatment space after the depressurizing operation, and in the pulse processing operation, the controller may controls the apparatus so that the fluid is supplied and the supply of the fluid is stopped by controlling the main valve.

According to the exemplary embodiment of the present invention, further comprising: a reservoir in which a fluid is stored, wherein the fluid pipe includes: a supply pipe for supplying a fluid to the treatment space; and a discharge pipe for discharging a fluid from the treatment space, and the supply pipe includes: an upstream supply pipe connected to the reservoir; a first downstream supply pipe branched from the upstream supply pipe and connected to the housing; and a second downstream supply pipe branched from the upstream supply pipe and connected to the housing, and both the main valve and the emergency valve are installed only in the first downstream supply pipe between the first downstream supply pipe and the second downstream supply pipe, the main valve includes: a first valve; and a second valve connected in series with the first valve, the controller controls, the fluid to be supplied to the treatment space through the second upstream supply pipe in the pressurizing operation, the fluid to be pulse supplied to the treatment space through the first upstream supply pipe in the pulse processing operation, and the first valve and the second valve to be opened and closed by opening and closing a passage of the fluid pipe supplying the fluid to the treatment space in the pulse processing operation, the pulse processing operation includes: an opening operation of a first valve in which the first valve is opened; and a closing operation of the first valve in which the first valve is closed, and the controller may controls a first opening operation of the second valve in which the second valve is opened, a closing operation of the second valve in which the second valve is closed, and a second opening operation of the second valve in which the second valve is opened to be sequentially performed during the opening operation of the first valve.

An exemplary embodiment of the present disclosure, an apparatus for processing a substrate, the apparatus may comprising, a housing having a treatment space for processing a substrate; a support unit for supporting a substrate in the treatment space; a fluid pipe which communicates with the treatment space and in which a fluid flows; a main valve installed in the fluid pipe and opening and closing a passage through which the fluid flows in the fluid pipe; and an emergency valve installed in the fluid pipe and opening and closing the passage through which the fluid flows in the fluid pipe.

According to the exemplary embodiment of the present invention, further comprising: a controller for controlling the main valve and the emergency valve, wherein the main valve and the emergency valve are arranged in series with each other, each of the main valve and the emergency valve is a normal open valve, the controller operates the main valve between the main valve and the emergency valve when the main valve is in a normal state to control the flow of the fluid in the fluid pipe, and controls the emergency valve to be maintained in an open state while the fluid pipe is controlled to be opened and closed by the main valve, and the controller operates the emergency valve between the main valve and the emergency valve when the main valve is in an abnormal state to control the flow of the fluid in the fluid pipe, and controls the main valve to be maintained in an open state while the fluid pipe may be controlled to be opened and closed by the emergency valve.

According to the exemplary embodiment of the present invention, wherein the controller includes: a loading operation of loading the substrate into the treatment space; after the loading operation, a processing operation of processing the substrate loaded into the treatment space with the fluid by supplying the fluid to the treatment space; and after the processing operation, an unloading operation of unloading the substrate from the treatment space, and the processing operation includes a supplying operation of pulse-supplying the fluid into the treatment space by controlling the main valve and the emergency valve, in the supplying operation, the controller controls an opening operation of the main valve in which the main valve is opened and a closing operation of the main valve in which the main valve is closed to be sequentially performed, the closing operation of the main valve being performed immediately after the opening operation of the main valve, and the controller may controls a first closing operation of the emergency valve in which the emergency valve is closed, an opening operation of the emergency valve in which the emergency valve is opened, and a second closing operation of the emergency valve in which the emergency valve is closed to be sequentially performed during the closing operation of the main valve.

According to the exemplary embodiment of the present invention, further comprising: a controller for controlling the main valve and the emergency valve, wherein the main valve and the emergency valve are arranged in parallel with each other, each of the main valve and the emergency valve is a normal open valve, the controller operates the main valve between the main valve and the emergency valve when the main valve is in a normal state to control the flow of the fluid in the fluid pipe, and controls the emergency valve to be maintained in a closed state while the fluid pipe is controlled to be opened and closed by the main valve, and the controller operates the emergency valve between the main valve and the emergency valve when the main valve is in an abnormal state to control the flow of the fluid in the fluid pipe, and controls the main valve to be maintained in a closed state while the fluid pipe may be controlled to be opened and closed by the emergency valve.

According to the exemplary embodiment of the present invention, wherein the fluid pipe includes: a first pipe in which the main valve is installed; and a second pipe in which the emergency valve is installed, and the second pipe is branched from the first pipe at a first point upstream from the main valve and joins the first pipe at a second point downstream from the main valve, the main valve includes a first valve and a second valve that open and close passages through which the fluid flows in the first pipe, respectively, between the first point and the second point, the controller includes: a loading operation of loading the substrate into the treatment space; after the loading operation, a processing operation of processing the substrate loaded into the treatment space with the fluid by supplying the fluid to the treatment space; and after the processing operation, an unloading operation of unloading the substrate from the treatment space, and the processing operation includes a supplying operation of pulse-supplying the fluid into the treatment space by controlling the main valve and the emergency valve, in the supplying operation, the controller controls an opening operation of the first valve in which the first valve is opened, and a closing operation of the first valve in which the first valve is closed to be sequentially performed, the closing operation of the first valve being performed immediately after the opening operation of the first valve, and the controller may controls a first closing operation of the second valve in which the second valve is closed, an opening operation of the second valve in which the second valve is opened, and a second closing operation of the second valve in which the second valve is closed to be sequentially performed during the closing operation of the first valve.

An exemplary embodiment of the present disclosure, an apparatus for processing a substrate, the apparatus comprising: a housing having a treatment space for processing a substrate; a support unit for supporting a substrate in the treatment space; a fluid pipe which communicates with the treatment space and in which a supercritical fluid flows; a main valve installed in the fluid pipe and opening and closing a passage through which the supercritical fluid flows in the fluid pipe; an emergency valve installed in the fluid pipe and opening and closing the passage through which the supercritical fluid flows; and a controller for controlling the main valve and the emergency valve, wherein the fluid pipe includes: a first pipe in which the main valve is installed; and a second pipe in which the emergency valve is installed, and the second pipe is branched from the first pipe at a first point upstream from the main valve and joins the first pipe at a second point downstream from the main valve, the main valve includes a first valve and a second valve that open and close passages through which the fluid flows in the first pipe, respectively, between the first point and the second point, the first valve and the second valve are arrange d in series, when the main valve is in a normal state, the controller operates the main valve between the main valve and the emergency valve to control the flow of fluid in the fluid pipe, and when the main valve is in an abnormal state, the controller operates the emergency valve between the main valve and the emergency valve to control the flow of the fluid in the fluid pipe, when the main valve is in the normal state, the controller includes an opening of the first valve in which the first valve is opened; and a closing operation of the first valve in which the first valve is closed immediately after the opening operation of the first valve, and the controller may controls the main valve so that a first opening operation of the second valve in which the second valve is opened, a closing operation of the second valve in which the second valve is closed, and a second opening operation of the second valve in which the second valve is opened are sequentially performed during the opening operation of the first valve.

According to the exemplary embodiment of the present invention, it is possible to prevent a decrease in an operation rate of an apparatus due to a failure of a valve.

According to the exemplary embodiment of the present invention, it is possible to extend a replacement cycle of a valve.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram schematically illustrating an exemplary embodiment of a drying chamber of FIG. 1.

FIG. 4 is a diagram schematically illustrating an exemplary embodiment of a fluid pipe coupled to the drying chamber of FIG. 1.

FIG. 5 is a flowchart schematically illustrating a process of processing a substrate using the substrate processing apparatus of FIG. 1.

FIG. 6 is a graph illustrating a change in a pressure in the drying chamber over time in a drying operation of FIG. 5.

FIG. 7 is a diagram schematically illustrating a valve operated by a controller to control the flow of a fluid when a main valve of FIG. 4 is in a normal state.

FIG. 8 is a graph schematically illustrating opening and closing states of valves over time when the main valve of FIG. 4 is in the normal state.

FIG. 9 is a diagram schematically illustrating a valve operated by the controller to control the flow of a fluid when the main valve of FIG. 4 is in an abnormal state.

FIG. 10 is a diagram schematically illustrating another exemplary embodiment of the fluid pipe of FIG. 3.

FIG. 11 is a diagram schematically illustrating a valve operated by a controller to control the flow of a fluid when a main valve of FIG. 10 is in a normal state.

FIG. 12 is a graph schematically illustrating opening and closing states of valves over time when the main valve of FIG. 10 is in the normal state.

FIG. 13 is a diagram schematically illustrating a valve operated by the controller to control the flow of a fluid when the main valve of FIG. 10 is in the abnormal state.

FIGS. 14 to 18 are diagrams schematically illustrating another exemplary embodiment of a fluid pipe coupled to the drying chamber of FIG. 1, respectively.

FIG. 19 is a graph schematically illustrating another exemplary embodiment of opening and closing states of valves over time when the main valve of FIG. 10 is in the normal state.

FIG. 20 is a graph schematically illustrating an example of a process of processing a substrate using a substrate processing apparatus.

FIG. 21 is a diagram schematically illustrating the liquid treating chamber wherein the second downstream supply pipe and the discharge pipe may communicate with each other and may be provided in a structure connected to the single port.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

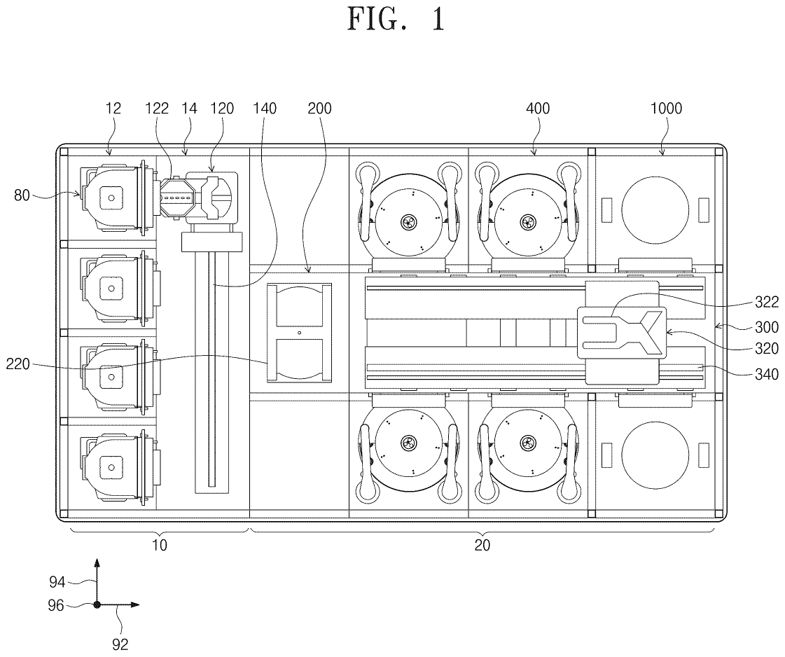

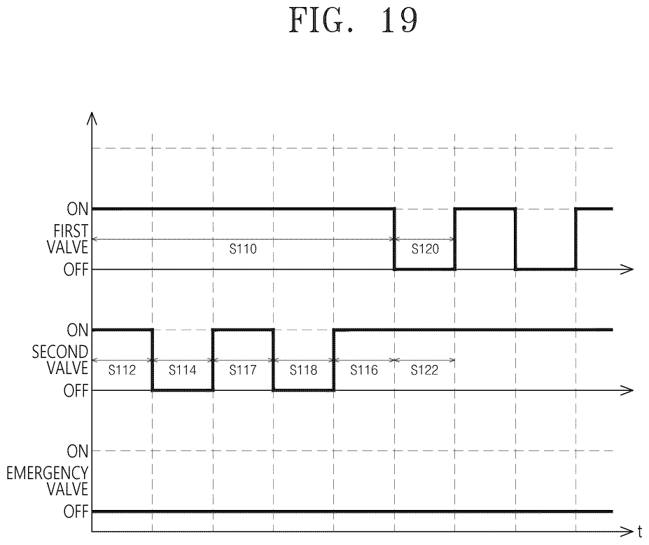

Hereinafter, exemplary embodiment of the present invention will be described with reference to FIGS. 1 to 20.

FIG. 1 is a top plan view schematically illustrating a substrate processing apparatus according to an exemplary embodiment of the present invention.

Referring to FIG. 1, a substrate processing apparatus 1 includes an index module 10, a treating module 20, and a controller 30. The index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plural, and the plurality of load ports 12 may be disposed in the second direction 94.

An index robot 120 is provided to the index frame 14. A guide rail 140 of which a longitudinal direction is the second direction 94 is provided within the index frame 14, and the index robot 120 may be provided to be movable along the guide rail 140. The index robot 120 includes a hand 122 on which the substrate W is placed. The hand 122 may be provided to move forward and backward, rotate around the third direction 96, and be movable along the third direction 96. The plurality of hands 122 is provided while being spaced apart from each other in the up and down direction, and is capable of independently moving forward and backward.

The treating module 20 includes a buffer unit 200, a transfer chamber 300, a liquid treating chamber 400, and a drying chamber 1000.

The buffer unit 200 provides a space in which the substrate W moved between the index module 10 and the transfer chamber 300 temporarily stays. The liquid treating chamber 400 performs a liquid treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction thereof is the first direction 92. The buffer unit 200 may be disposed between the index module 10 and the transfer chamber 300. A plurality of liquid treating chambers 400 is provided. The liquid treating chamber 400 may be disposed on a side portion of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

The transfer chamber 300 includes a transfer robot 320. A guide rail 340 whose longitudinal direction is provided in the first direction 92 is provided within the transfer chamber 300, and the transfer robot 320 may be provided to be movable on the guide rail 340. The transfer robot 320 includes a hand 322 on which the substrate W is placed. The hand 322 may be provided to move forward and backward, rotate around the third direction 96, and be movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face 201 and a rear face 202 of the buffer unit 200 are opened. The front face 201 of the buffer unit 200 is a face facing the index module 10, and the rear face 202 of the buffer unit 200 is a face facing the transfer chamber 300. The index robot 120 may approach the inside of the buffer unit 200 through the front face 201 of the buffer unit 200, and the transfer robot 320 may approach the buffer unit 200 through the rear face 202 of the buffer unit 200.

The controller 30 controls the substrate processing apparatus 1. The controller 30 controls each component of the liquid treating chamber 400, the transfer chamber 300, and the drying chamber 1000.

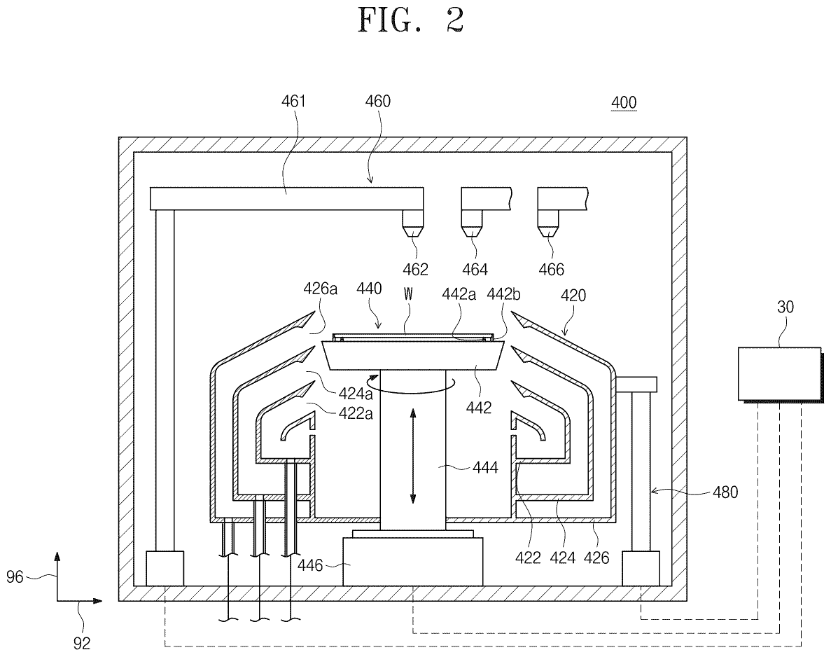

FIG. 2 is a diagram schematically illustrating an exemplary embodiment of a liquid treating chamber of FIG. 1.

Referring to FIG. 2, the liquid treating chamber 400 includes a housing 410, a cup 420, a support unit 440, a nozzle unit 460, and a lifting unit 480.

The housing 410 is provided in a generally rectangular parallelepiped shape. The cup 420, the support unit 440, the nozzle unit 460, and the lifting unit 480 are disposed within the housing 410.

The cup unit 420 has a treatment space 402 in which an upper portion is opened. The cup unit 420 includes an inner cup 422, an intermediate cup 424, and an outer cup 426. The inner cup 422, the intermediate cup 424, and the outer cup 426 each have recovery spaces for recovering a liquid used for processing the substrate W. The inner cup 422, the intermediate cup 424, and the outer cup 426 are each provided in a ring shape surrounding the support unit 440. When the liquid treatment process is performed, the treatment liquid scattered by rotation of the substrate W flows into the recovery spaces through the inlets 422a, 424a, and 426a of the inner cup 422, the intermediate cup 424, and the outer cup 426. According to the exemplary embodiment, the inner cup 422 is disposed to surround the support unit 440, the intermediate cup 424 is disposed to surround the inner cup 422, and the outer cup 426 is disposed to surround the intermediate cup 424. The intermediate cup inlet 424a through which the liquid flows into the intermediate cup 424 may be positioned above the inner cup inlet 422a through which the liquid flows into the inner cup 422, and the outer cup inlet 426a through which the liquid flows into the outer cup 426 may be positioned above the intermediate cup inlet 424a through which the liquid flows into the intermediate cup 424.

The support unit 440 supports the substrate W in the treatment space 402. The support unit 440 includes a spin chuck 442 and a drive shaft 444. An upper surface of the spin chuck 442 may be provided in a generally circular shape, and may have a diameter larger than a diameter of the substrate W. A chuck pin 442b is provided at an edge of the spin chuck 442. The chuck pin 442b is provided to protrude upward from the spin chuck 442. The chuck pin 442b supports a side portion of the substrate W so that the substrate W does not deviate from the support unit 440 when the substrate W is rotated. Also, a support pin 442a is provided to the spin chuck 442. The support pin 442a is provided with a top end protruding from the spin chuck 442 such that the substrate W is spaced a certain distance from the spin chuck 442. The support pin 442a is disposed closer to a center of the spin chuck 442 than the chuck pin 442b. The drive shaft 444 is driven by the driver 446, is connected to a center of a bottom surface of the substrate W, and rotates the spin chuck 442 with respect to its central axis.

The nozzle unit 460 supplies a treatment liquid onto the substrate W supported on the support unit 440. The treatment liquid may be provided in a plurality of types, and may be sequentially supplied onto the substrate W. The nozzle unit 460 includes a support frame 470, an arm 472, a first nozzle 462, a second nozzle 464, a third nozzle 466, and a nozzle driver 468.

The first nozzle 462 supplies a first treatment liquid onto the substrate W. The second nozzle 464 supplies a second treatment liquid onto the substrate W. The third nozzle 466 supplies the third treatment liquid onto the substrate W. The first treatment liquid, the second treatment liquid, and the third treatment liquid are different types of treatment liquids. The first treatment liquid, the second treatment liquid, and the third treatment liquid may be an acidic component, an alkali component, or a neutral component. For example, the first treatment liquid, the second treatment liquid, and the third treatment liquid may be an acid component, such as sulfuric acid, hydrofluoric acid, phosphoric acid, or hydrochloric acid, or may be an alkali component, such as ammonia, or water.

Meanwhile, a nozzle unit 460 for supplying another type of treatment liquid may be further provided. For example, the nozzle unit 460 may further include a nozzle for supplying an organic solvent, such as isopropyl alcohol (IPA).

The support frame 470 supports the arm 472. A plurality of arms 472 is provided so that each nozzle 490 is installed. Each nozzle 490 is installed at an end of the arm 472. The arm 472 is provided side by side in one direction. The nozzle driver 468 has a drive shaft 474 and a driver 476. The nozzle driver 468 drives the support frame 470 such that the nozzles 490 move between a process position and a standby position R. The process position is a position at which the nozzle 490 supplies the treatment liquid onto the substrate W. The standby position is a position at which the nozzle 490 which has completed supplying the treatment liquid onto the substrate W waits until the next processing of the substrate W.

The lifting unit 480 adjusts a relative height between the cup 420 and the support unit 440. According to an example, the lifting unit 480 moves the cup 420 in the vertical direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the treatment liquids may be separated and recovered. Unlike the description, the cup 420 may be fixedly installed, and the lifting unit 480 may move the support unit 440 in the vertical direction.

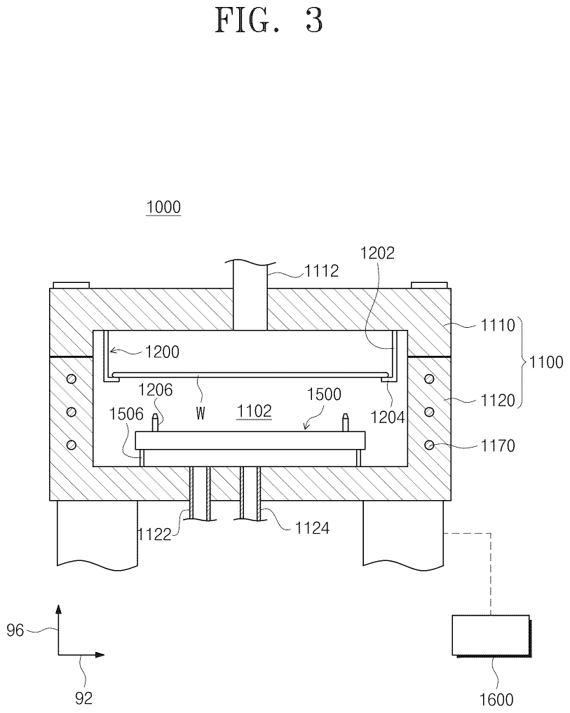

FIG. 3 is a diagram schematically illustrating an exemplary embodiment of a drying chamber of FIG. 1.

Referring to FIG. 3, the drying chamber 1000 includes a housing 1100, a filler member 1500, a support unit 1200, and a driver 1600. The drying chamber 1000 performs a process of removing a liquid on the substrate W by supplying a fluid. For example, the fluid supplied to the drying chamber 1000 may be a fluid in a supercritical state. The drying chamber 1000 is connected to a reservoir 1320 through a supply pipe 2100 of a fluid pipe 2000. Also, the drying chamber 1000 is connected to a discharge pipe 2200 of the fluid pipe 2000 to discharge the fluid to the outside.

The housing 1100 provides a treatment space 1102 in which a drying process is performed. The housing 1100 includes an upper body 1110 and a lower body 1120. The upper body 1110 and the lower body 1120 are combined to form the treatment space 1102. The upper body 1110 is provided on the lower body 1120. The lower body 1120 is relatively moved from the upper body 1110. Alternatively, the upper body 1110 is relatively moved from the lower body 1120. As the lower body 1120 or the upper body 1110 is moved relative to the other one, the treatment space 1102 is opened or closed. As the treatment space 1102 is opened, the substrate W may be loaded in or unloaded. According to the exemplary embodiment, a position of the upper body 1110 is fixed, and the lower body 1120 may be raised or lowered by the driver 1600. According to the exemplary embodiment, the driver 1600 may be provided as a cylinder. During the drying process, the upper body 1110 and the lower body 1120 are in close contact with each other so that the treatment space 1102 is sealed from the outside.

The lower body 1120 is provided with a first supply port 1122 and a discharge port 1124. The first supply port 1122 is provided at a position deviated from the center of the lower body 1120 when viewed from above. The discharge port 1124 is formed at the center of the lower body 1120 when viewed from above.

A second supply port 1112 is formed in the upper body 1110. When viewed from above, the second supply port 1112 is formed at the center of the upper body 1110.

The fluid is supplied to the treatment space 1102 through the first supply port 1122 and the second supply port 1112. The fluid in the treatment space 1102 is discharged to the outside of the drying chamber 1000 through the discharge port 1124. The first supply port 1122, the second supply port 1112, and the discharge port 1124 communicate with the fluid pipe 2000.

The first supply port 1122 allows the fluid to be supplied to an area of the treatment space 1102 lower than the substrate W. The second supply port 1112 allows the fluid to be supplied to an area of the treatment space 1102 higher than the substrate W.

A heater 1170 is installed in the housing 1100. According to the exemplary embodiment, the heater 1170 is located inside a wall of the housing 1100. The heater 1170 heats the treatment space 1102 so that the fluid supplied to the treatment space 1102 maintains a supercritical state.

The filler member 1500 is disposed in the treatment space 1102. The filler member 1500 is supported by the support 1506 to be spaced apart upward from the bottom surface of the lower body 1102. The support 1506 is provided in a rod shape. A plurality of supports 1506 is disposed to be spaced apart from each other by a predetermined distance. The filler member 1500 prevents the substrate W from being damaged by discharging the fluid supplied through the first supply port 1122 directly toward the back surface of the substrate W. The filler member 1500 occupies a volume within the treatment space 1102. Accordingly, when the fluid is supplied to the treatment space 1102, the pressure of the treatment space 1102 may be rapidly pressurized.

The support unit 1200 supports the substrate W in the treatment space. The support unit 1200 includes a fixed rod 1202, a holder 1204, and a support pin 1206.

The fixed rod 1202 is fixedly installed on the upper body 1110 so as to protrude downward from the bottom surface of the upper body 1110. The fixed rod 1202 is provided in a vertical direction in its longitudinal direction. A plurality of fixed rods 1202 is provided and is positioned to be spaced apart from each other. The fixed rods 1202 are disposed at positions where the substrate W does not interfere with the fixed rods 1202 when the substrate W is loaded in or unloaded from a space surrounded by the fixed rods 1202. The holder 1204 is coupled to each fixed rod 1202.

The holder 1204 extends in a direction from a lower end of the fixed rod 1202 toward a space surrounded by the fixed rods 1202. The holder 1204 is provided in a direction perpendicular to the fixed rod 1202. The holder 1204 supports the substrate W when the substrate W is loaded or unloaded.

The support pin 1206 is installed on the upper surface of the filler member 1500. The support pin 1206 may be moved up and down as the lower body 1120 is moved up and down by the driver 1600. After the substrate W is loaded into the treatment space 1102 to be seated on the holder 1204 and the drying chamber 1000 is sealed, the support pin 1206 is moved up and down by the driver 1600. That is, the end of the substrate W is supported by the support pin 1206 in the process of processing the substrate.

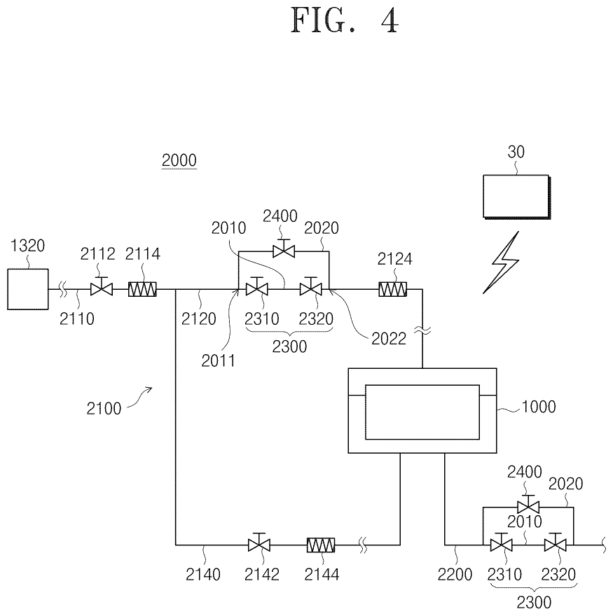

FIG. 4 is a diagram schematically illustrating an exemplary embodiment of the fluid pipe.

Referring to FIG. 4, the fluid pipe 2000 includes a supply pipe 2100 and a discharge pipe 2200. The fluid pipe 2000 is a pipe for supplying a fluid to the treatment space 1102 or discharging the fluid from the treatment space 1102. The fluid pipe 2000 provides a passage through which a fluid flows.

The supply pipe 2100 is connected to the reservoir 1320. The reservoir 1320 is provided as a supply tank. The reservoir 1320 stores a fluid therein. According to the exemplary embodiment, the reservoir 1320 may store a fluid therein in a supercritical state.

The supply pipe 2100 supplies a fluid from the reservoir 1320 to the treatment space 1102. The supply pipe 2100 includes an upstream supply pipe 2110, a first downstream supply pipe 2120, and a second downstream supply pipe 2140.

The upstream supply pipe 2110 is connected to the reservoir 1320. The upstream supply pipe 2110 is branched to the first downstream supply pipe 2120 and the second downstream supply pipe 2140. The first downstream supply pipe 2120 connects the upstream supply pipe 2110 and the second supply port 1112. The first downstream supply pipe 2120 supplies a fluid to the treatment space 1102 at a position higher than the substrate W. The second downstream supply pipe 2140 connects the upstream supply pipe 2110 and the first supply port 1122. The second downstream supply pipe 2140 supplies a fluid to the treatment space 1102 at a position lower than the substrate W.

A main valve 2112 and a main heater 21114 are installed in the upstream supply pipe 2110. The main valve 2112 opens and closes an inner passage of the upstream supply pipe 2110. The main heater 21114 heats the passage of the upstream supply pipe 2110. The main heater 21114 is installed downstream of the main valve 2112.

The first downstream supply pipe 2120 includes a first pipe 2010 and a second pipe 2020. Also, a main valve 2300, an emergency valve 2400, and a first heater 2124 are installed in the first downstream supply pipe 2120. The main valve 2300 opens and closes the first downstream supply pipe 2120. The main valve 2300 includes a first valve 2310 and a second valve 2320. The first valve 2310 and the second valve 2320 are connected in series. For example, the main valve 2300 may be a normal close valve. The normal close valve is a valve in which the diaphragm maintains a state of opening/closing the passage of the fluid in the valve by elastic force when no elastic force is applied, and opens the passage of the fluid by the supply of external force, such as a fluid. The external force may be a gas pressure that provides a driving pressure for driving the diaphragm of the main valve 2300. The emergency valve 2400 opens and closes the first downstream supply pipe 2120. For example, both the main valve 2300 and the emergency valve 2400 may be normal close valves. Each of the main valve 2300 and the emergency valve 2400 is controlled by a controller 30.

The main valve 2300 is installed in the first pipe 2010. The emergency valve 2400 is installed in the second pipe 2020. The second pipe 2020 is branched from the first pipe 2010 at a first point 2011 upstream from the main valve 2300. Also, the second pipe 2020 is joined to the first pipe 2010 at a second point 2012 downstream from a point where the main valve 2300 is installed. That is, the first valve 2310 and the second valve 2320 are each installed between the first point 2011 and the second point 2012 of the first pipe 2010. Further, the first valve 2310 and the second valve 2320 are connected in parallel to the emergency valve 2400.

The first heater 2124 heats the passage of the first downstream supply pipe 2120. The first heater 2124 is installed downstream from the main valve 2300 and the emergency valve 2400.

A second downstream supply pipe valve 2142 and a second heater 2144 are installed at the second downstream supply pipe 2140. The second downstream supply pipe valve 2142 opens and closes the second downstream supply pipe 2140. The second heater 2144 heats the passage of the second downstream supply pipe 2140. The second heater 2144 is installed downstream from the second downstream supply pipe valve 2142.

The discharge pipe 2200 is connected to the discharge port 1124. The discharge pipe 2200 discharges a fluid from the treatment space 1102 to the outside. The discharge pipe 2200 includes a first pipe 2010 and a second pipe 2020. Also, the main valve 2300 and the emergency valve 2400 are installed in the discharge pipe 2200. The arrangement of the first pipe 2010 and the second pipe 2020 provided in the discharge pipe 2200, the arrangement of the main valve 2300 and the emergency valve 2400 provided in the discharge pipe 2200, and the operation thereof may be provided the same as or similar to the arrangement of the first pipe 2010 and the second pipe 2020 provided in the first downstream supply pipe 2120, the arrangement of the main valve 2300 and the emergency valve 2400 provided in the discharge pipe 2200, and the operation thereof.

The main valve 2300 is provided with a leak sensor capable of detecting whether a valve is leaking. For example, the main valve 2300 is driven by a solenoid valve, and the leak detection sensor may be provided to detect whether a leakage occurs in a pipe connecting the main valve and the solenoid valve. In addition, the leak detection sensor may be provided to detect whether a leakage occurs in a flow path provided in the main valve 2300. In addition, the leak detection sensor may be provided to detect whether a leakage occurs in the first pipe 2010 downstream from the main valve 2300. For example, each leak detection sensor is a pressure gauge that measures pressure in each flow path, and may detect whether a leakage occurs based on the measured pressure value.

Hereinafter, a case in which the leak is not detected in the main valve 2300 is referred to as a normal state of the main valve, and a case in which the leak is detected in the main valve 2300 is referred to as an abnormal state of the main valve.

Hereinafter, the present invention will be described based on a structure in which the main valve 2300 and the emergency valve 2400 are installed in the first downstream supply pipe 120 as an example.

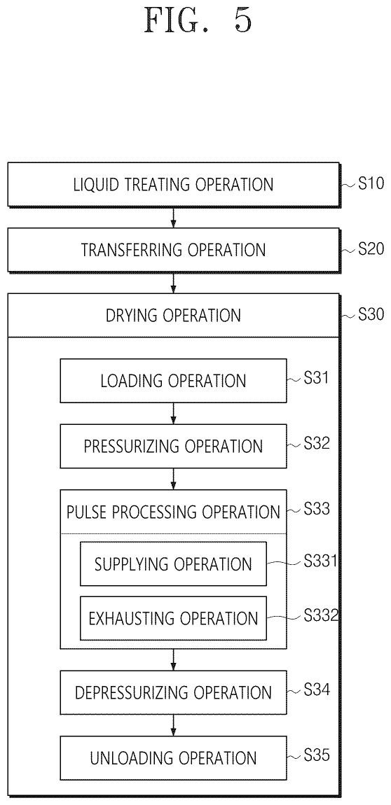

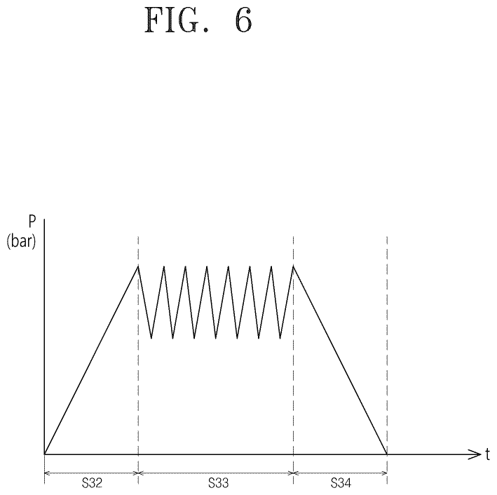

FIG. 5 is a flowchart schematically illustrating a process of processing a substrate using the substrate processing apparatus of FIG. 1, and FIG. 6 is a graph illustrating a change in a pressure in the drying chamber over time in a drying operation of FIG. 5.

Referring to FIGS. 5 and 6, the substrate processing process includes a liquid treating operation S10, a transferring operation S20, and a drying operation S30.

In the liquid treating operation S10, the substrate W is liquid-treated in the liquid treating chamber 400. In the liquid treating operation S10, a rotating chemical, rinse liquid, and organic solvent are sequentially supplied to liquid-treat the substrate W. The chemical may be an acid or alkali containing liquid. The rinse liquid may be pure water. The organic solvent may be isopropyl alcohol (IPA). When the liquid treating operation S10 is terminated, a transferring operation S20 is performed.

In a state in which a liquid film of the organic solvent is formed on the substrate W in the transferring operation S20, the substrate W is transferred from the liquid treating chamber 400 to the drying chamber 1000 by the transfer robot 320. After the substrate W is transferred to the drying chamber 1000, a drying operation S30 is performed.

In the drying operation S30, the substrate W is dried in the drying chamber 1000 using a supercritical fluid. The drying operation S30 includes a loading operation S31, a pressurizing operation S32, a pulse processing operation S33, a depressurizing operation S34, and an unloading operation S35.

In the loading operation S31, the substrate W is loaded into the treatment space 1102. In the loading operation S31, the upper body 1110 or the lower body 1120 is moved relative to each other by the driver 1600 to be spaced apart from each other. In a state in which the upper body 1110 and the lower body 1120 are spaced apart from each other, the transfer robot 320 loads the substrate W into the treatment space 1102. When the loading of the substrate W is completed, the lower body 1120 moves upward to seal the treatment space 1102, and a pressurizing operation S32 is performed.

In the pressurizing operation S32, the pressure of the treatment space 1102 is increased to a process pressure. In the pressurizing operation S32, the supercritical fluid is supplied to the second downstream supply pipe 2140 and the supercritical fluid is introduced into the treatment space 1102 through the first supply port 1122. Accordingly, the treatment space 1102 is pressurized. When the pressure of the treatment space 1102 is increased to the process pressure, a pulse processing operation S33 is performed.

In the pulse processing operation S33, a supplying operation S331 of supplying the supercritical fluid to the treatment space 1102 and an exhausting operation S332 of exhausting the fluid from the treatment space 1102 are sequentially and repeatedly performed. In the supplying operation S331, the fluid is pulse-supplied to the treatment space 1102 through the first downstream supply pipe 2120. In the supplying operation S331, whether or not the supercritical fluid is supplied is controlled by controlling the operation of the valve installed in the first downstream supply pipe 2120.

Similarly, in the exhausting operation S332, the fluid is pulse-exhausted from the treatment space 1102 through the discharge pipe 2100. In the exhausting operation S332, whether to discharge the supercritical fluid is controlled by controlling the operation of the valve installed in the discharge pipe 2200. After the pulse processing operation S33 is terminated, a depressurizing operation S34 is performed.

In the depressurizing operation S34, the pressure in the treatment space 1102 is lowered to normal pressure. In the depressurizing operation S34, the fluid in the treatment space 1102 is discharged by the discharge pipe 2200. When the depressurizing operation S34 is completed, an unloading S35 is performed.

In the unloading operation S35, the substrate W is unloaded from the treatment space 1102. In the unloading operation S35, the upper body 1110 or the lower body 1120 is moved relative to each other by the driver 1600 to be spaced apart from each other as in the loading operation S31. In a state in which the upper body 1110 and the lower body 1120 are spaced apart from each other, the transfer robot 320 unloads the substrate W from the treatment space 1102.

Hereinafter, the change in the opening and closing state of the valve will be described using the graph. In each graph, “ON” indicates the open state of the valve, and “OFF” indicates the closed state of the valve. Also, in each drawing, a valve filled with the inside indicates the closed state of the valve, and a valve not filled with the inside indicates the open state of the valve.

In a normal state of the main valve 2300, the main valve 2300 between the main valve 2300 and the emergency valve 2400 is operated to control the flow of supercritical fluid in the supply pipe 2100.

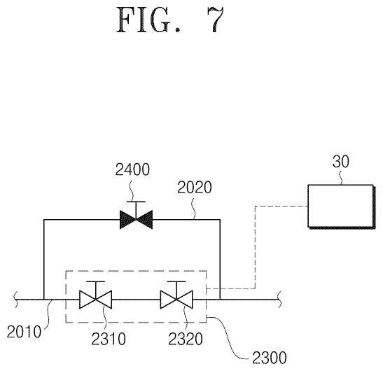

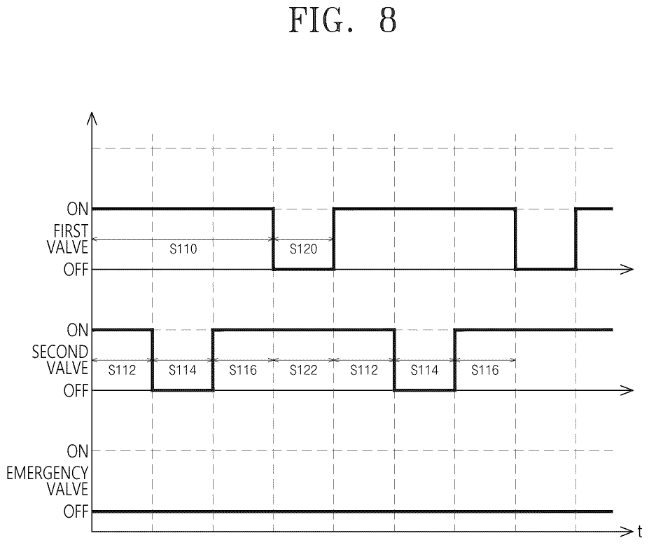

FIG. 7 is a diagram schematically illustrating a valve operated by the controller to control the flow of a fluid when the main valve of FIG. 4 is in the normal state, and FIG. 8 is a graph schematically illustrating opening and closing states of valves over time when the main valve of FIG. 4 is in the normal state.

Referring to FIGS. 7 and 8, when the main valve 2300 is in the normal state, the main valve 2300 is opened and closed, and the emergency valve 2400 maintains a closed state. In this case, the supplying operation S331 and the exhausting operation S332 are performed by the first valve 2310 and the second valve 2320. Hereinafter, the process of performing the supplying operation S331 is to be described, but this may also be applied to the exhausting operation S332.

The supplying operation S331 includes an opening operation S110 of the first valve and a closing operation S140 of the first valve. In the opening operation S130 of the first valve, the first valve 2310 is opened. In the closing operation S120 of the first valve, the first valve 2310 is closed.

The opening operation S110 of the first valve and the closing operation S120 of the first valve are sequentially performed. The opening operation S110 of the first valve and the closing operation S120 of the first valve are respectively performed for a predetermined time. According to the exemplary embodiment, a time during which the opening operation S110 of the first valve is performed may be longer than a time during which the closing operation S120 of the first valve is performed.

During the opening operation S110 of the first valve, the second valve 2320 is opened and closed. During the opening operation S110 of the first valve, a first opening operation S112 of the second valve, a closing operation S114 of the second valve, and a second opening operation S116 of the second valve are sequentially performed. That is, in the opening operation S110 of the first valve, the first valve 2310 is maintained in the opening state and the opening and closing state of the second valve 2320 is changed in the order of “opening-closing-opening”.

The first opening operation S112 of the second valve, the closing operation S114 of the second valve, and the second opening operation S116 of the second valve are each performed for a predetermined time. In one exemplary embodiment, a time during which each of the operations S112, S114, and S116 is performed may be the same. For example, a time during which each of the operations S112, S114, and S116 is performed may be the same as the time during which the closing operation S120 of the first valve is performed.

During the closing operation S120 of the first valve, a third opening operation S122 of the second valve 2320 in which the second valve 2320 is opened is performed. That is, the second valve 2320 maintains the open state during the closing operation S120 of the first valve.

The opening operation S110 of the first valve and the closing operation S120 of the first valve are continuously performed. That is, after the closing operation S120 of the first valve is terminated, the opening operation S110 of the first valve is immediately performed again. Also, the opening operation S110 of the first valve and the closing operation S120 of the first valve are repeatedly performed a plurality of times.

First, in the first opening operation S112 of the second valve, each of the first valve 2310 and the second valve 2320 is opened. Accordingly, the passage of the fluid pipe 2000 is opened. Thereafter, in the closing operation S114 of the second valve, the first valve 2310 is maintained in the open state, and the second valve 2320 is closed. Accordingly, the passage of the fluid pipe 2000 is closed. Thereafter, in the second opening operation S116 of the second valve, the first valve 2310 is maintained in the open state, and the second valve 2320 is opened. Accordingly, the passage of the fluid pipe 2000 is opened. Thereafter, in the third opening operation S122 of the second valve, the first valve 2310 is closed, and the second valve 2320 is maintained in the open state. Accordingly, the passage of the fluid pipe 2000 is closed. Thereafter, the above process is repeated until the supplying operation S331 is terminated.

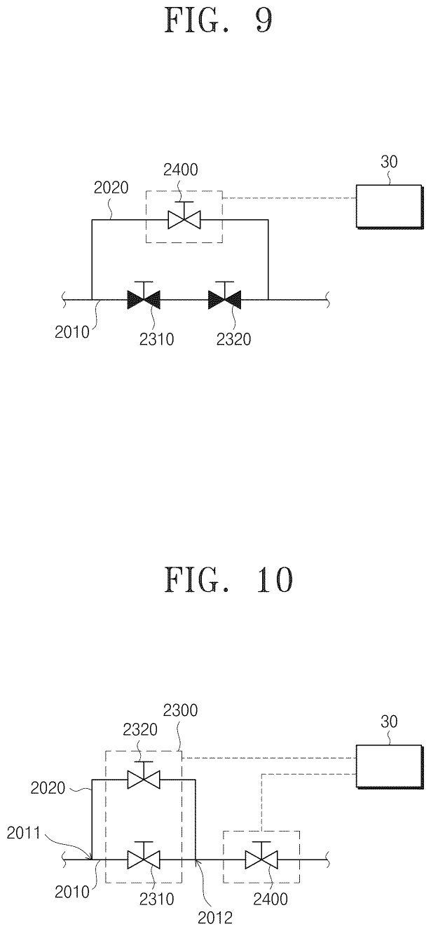

FIG. 9 is a diagram schematically illustrating a valve operated by the controller to control the flow of a fluid when the main valve of FIG. 4 is in the abnormal state.

Referring to FIG. 9, when a leak occurs in any one of the first valve 2310 and the second valve 2320 and it is determined that the valve is abnormal, the flow of the supercritical fluid in the fluid pipe 2000 is controlled by operating the emergency valve 2400 between the main valve 2300 and the emergency valve 2400.

That is, the main valve 2300 is closed, and the emergency valve 2400 is opened and closed. In this case, the flow of the fluid in the fluid pipe 2000 is controlled by operating the emergency valve 2400. Accordingly, the supplying operation S331 is performed by the control of the emergency valve 2400, and the main valve 2300 maintains the closed state while the flow of the fluid is controlled by the emergency valve 2400.

When the main valve 2300 is in the abnormal state, the emergency valve 2400 repeatedly opens and closes, and thus the supplying operation S331 is performed. The emergency valve 2400 repeatedly opens and closes at regular time intervals to pulse-supply the fluid.

Since the main valve 2300 and the emergency valve 2400 are provided as normal narrows valves, while the flow of the fluid is controlled by controlling the main valve 2300, the emergency valve 2400 always maintains the closed state even when external force is not applied to the emergency valve 2400. Therefore, it is not necessary to consume energy so that the emergency valve 2400 maintains the closed state while the flow of the fluid is controlled by controlling the main valve 2300.

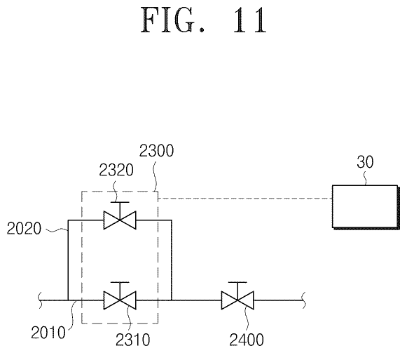

FIG. 10 is a diagram schematically illustrating another exemplary embodiment of the fluid pipe of FIG. 3.

Referring to FIG. 10, the fluid pipe 2000 includes a first pipe 2010 and a second pipe 2020. The first valve 2310 and the emergency valve 2400 are installed in the first pipe 2010, and the second valve 2320 is installed in the second pipe 2020. Further, the emergency valve 2400 is installed at a point downstream of the first valve 2310 on the first pipe 2010. That is, the first valve 2310 and the second valve 2320 are connected in parallel with each other, the first valve 2310 and the emergency valve 2400 are connected in series with each other, and the second valve 2320 and the emergency valve 2400 are connected in series with each other.

One of the main valve 2300 and the emergency valve 2400 is maintained in an open state while the fluid pipe 2000 is opened and closed by the other of the two valves. For example, the first valve 2310, the second valve 2320, and the emergency valve 2400 may be provided as normal open valves. The normal open valve is a valve which maintains a state in which the diaphragm opens and closes the passage of the fluid in the valve by elastic force in a state in which external force is not provided, and the diaphragm closes the passage of the fluid by supply of external force, such as fluid. The external force may be a gas pressure that provides a driving pressure for driving the diaphragm of the main valve 2300.

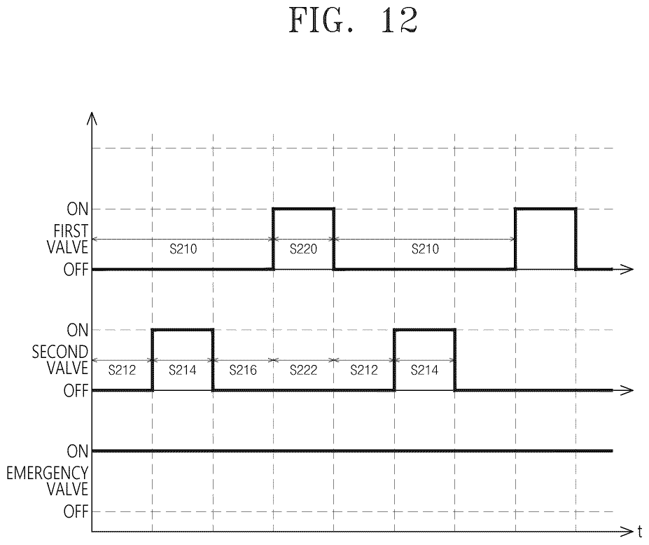

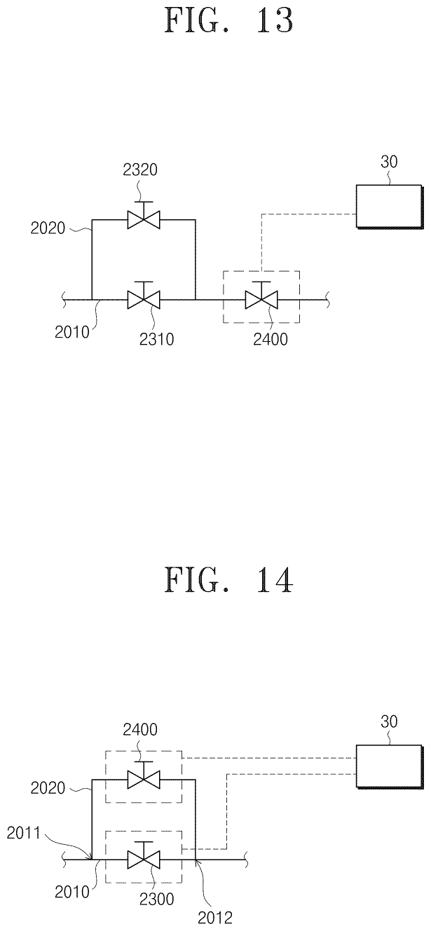

FIG. 11 is a diagram schematically illustrating a valve operated by the controller to control the flow of a fluid when the main valve of FIG. 10 is in the normal state, and FIG. 12 is a graph schematically illustrating opening and closing states of valves over time when the main valve of FIG. 10 is in the normal state.

Referring to FIG. 11, when the main valve 2300 is in the normal state, the emergency valve 2400 is maintained in an open state, and a pulse processing operation S33 is performed by the main valve 2300. The controller 30 opens and closes the main valve 2300 to pulse-supply and pulse-exhaust the fluid. In this case, the supplying operation S331 and the exhausting operation S332 are performed by the first valve 2310 and the second valve 2320.

Referring to FIG. 12, the supplying operation S331 includes a closing operation S210 of the first valve and an opening operation S220 of the first valve. The opening operation S110 of the first valve and the closing operation S120 of the first valve are sequentially performed. The closing operation S210 of the first valve and the opening operation S220 of the first valve are each performed for a predetermined time. According to the exemplary embodiment, a time during which the opening operation S110 of the first valve is performed may be longer than a time during which the closing operation S120 of the first valve is performed.

During the closing operation S220 of the first valve, the second valve 2320 is opened and closed. During the closing operation S220 of the first valve, a first closing operation S212 of the second valve, an opening operation S214 of the second valve, and a second closing operation S216 of the second valve are sequentially performed. That is, in the closing operation S210 of the first valve, the first valve 2310 maintains the closed state and the opening and closing state of the second valve 2320 is changed in the order of “close-open-close”.

The first closing operation S212 of the second valve, the opening operation S214 of the second valve, and the second closing operation S216 of the second valve are each performed for a predetermined time. In one exemplary embodiment, a time during which each of the operations S212, S214, and S216 is performed may be the same. For example, a time during which each of the operations S212, S214, and S216 is performed may be the same as the time during which the opening operation S220 of the first valve is performed.

A third closing operation S222 of the second valve in which the second valve 2320 is closed is performed during the opening operation S220 of the first valve. That is, the second valve 2320 maintains the closed state during the opening operation S220 of the first valve.

The opening operation S210 of the first valve and the closing operation S220 of the first valve are continuously performed. That is, after the closing operation S220 of the first valve is terminated, the opening operation S210 of the first valve is immediately performed again. Also, the opening operation S210 of the first valve and the closing operation S220 of the first valve are repeatedly performed a plurality of times.

First, in the first closing operation S212 of the second valve, the first valve 2310 and the second valve 2320 are each closed. Accordingly, the passage of the fluid pipe 2000 is closed. Thereafter, in the operation S214 of opening the second valve, the first valve 2310 is maintained in the closed state, and the second valve 2320 is opened. Accordingly, the passage of the fluid pipe 2000 is opened. Thereafter, in the second closing operation S216 of the second valve, the first valve 2310 is maintained in the closed state, and the second valve 2320 is closed. Accordingly, the passage of the fluid pipe 2000 is closed. Thereafter, in the third closing operation S222 of the second valve, the first valve 2310 is opened, and the second valve 2320 is maintained in the closed state. Accordingly, the passage of the fluid pipe 2000 is opened. Thereafter, the above process is repeated until the pulse processing operation S33 is terminated.

Since the main valve 2300 and the emergency valve 2400 are provided as normal open valves, while controlling the flow of the fluid by controlling the main valve 2300, the emergency valve 2400 is always maintained in the open state without applying external force to the emergency valve 2400. Therefore, there is no need to consume energy so that the emergency valve 2400 is maintained in the open state while controlling the flow of the fluid by controlling the main valve 2300.

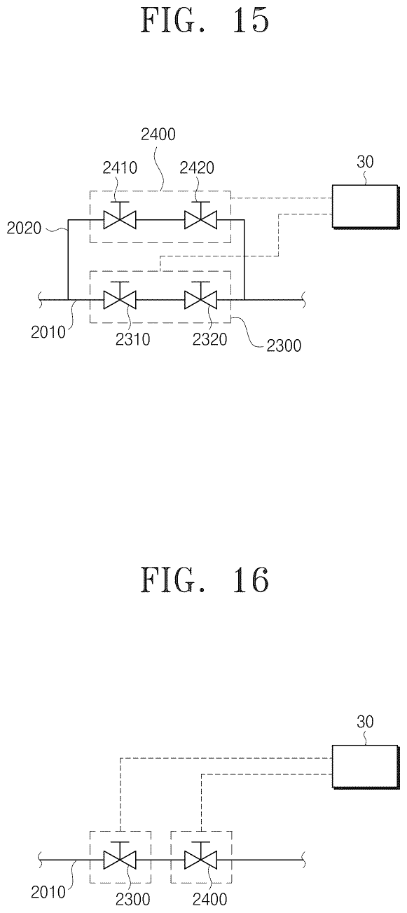

FIG. 13 is a diagram schematically illustrating a valve operated by the controller to control the flow of the fluid when the main valve of FIG. 10 is in the abnormal state.

Referring to FIG. 13, when a leak occurs in any one of the first valve 2310 and the second valve 2320 and it is determined that the valve is in the abnormal state, the main valve 2300 is maintained in the open state. In this case, the controller 30 controls the flow of the supercritical fluid in the fluid pipe 2000 by operating the emergency valve 2400. Accordingly, the supplying operation S331 and the exhausting operation S332 are performed by the emergency valve 2400.

That is, when the main valve is in the abnormal state, the pulse processing operation S33 is performed by repeatedly opening and closing the emergency valve 2400 alone.

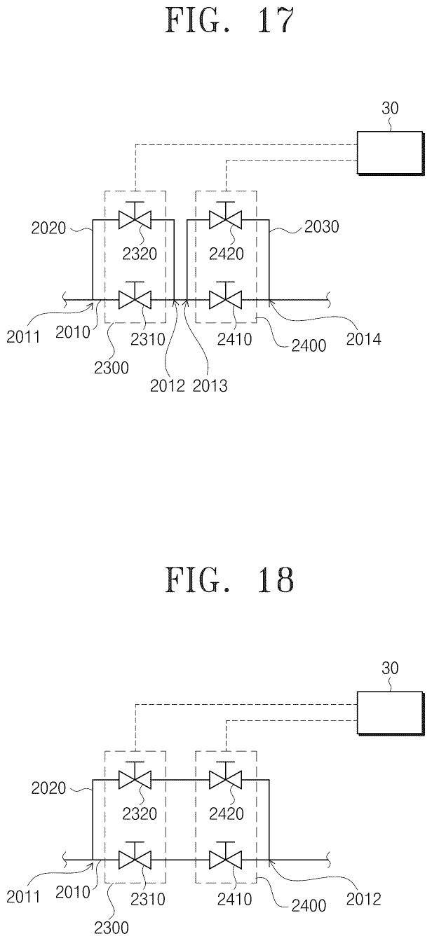

Hereinafter, various exemplary embodiments of the fluid pipe will be described with reference to FIGS. 14 to 18.

FIG. 14 is a diagram schematically illustrating another exemplary embodiment of the fluid pipe coupled to the drying chamber of FIG. 1.

Referring to FIG. 14, the main valve 2300 and the emergency valve 2400 are each provided as a single valve. The main valve 2300 is installed in the first pipe 2010, and the emergency valve 2400 is installed in the second pipe 2020. The main valve 2300 is provided between the first point 2011 and the second point 2012. The main valve 2300 and the emergency valve 2400 are connected in parallel with each other.

In the exemplary embodiment of FIG. 14, when the main valve 2300 is in the normal state, the controller 30 opens and closes the main valve 2300 and the emergency valve 2400. The main valve 2300 and the emergency valve 2400 are controlled in the same manner as the first valve 2310 and the second valve 2320 connected in parallel in the exemplary embodiment of FIG. 10. For example, the main valve 2300 of FIG. 14 may correspond to the first valve 2310 of FIG. 10 and the emergency valve 2400 of FIG. 14 may correspond to the second valve 2320 of FIG. 10.

In the exemplary embodiment of FIG. 14, when the main valve is in the abnormal state, the main valve 2300 is closed, and the controller 30 opens and closes the emergency valve 2400. In this case, the passage of the first pipe 2010 is closed, and the supplying operation S331 and the exhausting operation S332 are performed by the emergency valve 2400.

FIG. 15 is a diagram schematically illustrating another exemplary embodiment of the fluid pipe coupled to the drying chamber of FIG. 1.

Referring to FIG. 15, the main valve 2300 includes the first valve 2310 and the second valve 2320, and the emergency valve 2400 includes a first emergency valve 2410 and a second emergency valve 2420. The first valve 2310 and the second valve 2320 are provided in series with each other in the first pipe 2010, and the first emergency valve 2410 and the second emergency valve 2420 are provided in series with each other in the second pipe 2020. Each of the main valves 2310 and 2320 and each of the emergency valves 2410 and 2420 are connected in parallel with each other.

In the exemplary embodiment of FIG. 15, when the main valve 2300 is in the normal state, the first emergency valve 2410 and the second emergency valve 2420 are maintained the closed state. Accordingly, the fluid flows only through the first pipe 2010. In this case, the controller 30 opens and closes the inside of the first pipe 2010 by the first valve 2310 and the second valve 2320 to control the supplying operation S331 and the exhausting operation S332 to be performed. For example, in the normal state of the main valve 2300, the first valve 2310 and the second valve 2320 are controlled to supply the fluid and stop the supply of the fluid by changing the opening and closing state thereof over time, similar to the first valve 2310 and the second valve 2320 in the exemplary embodiment of FIG. 7.

In the exemplary embodiment of FIG. 15, when the main valve 2300 is in the abnormal state, the first valve 2310 and the second valve 2320 are maintained the closed state. Accordingly, the fluid flows only through the second pipe 2020. In this case, the controller 30 controls the pulse processing operation S33 to be performed by the first emergency valve 2410 and the second emergency valve 2420. For example, in the abnormal state of the main valve 2300, the first emergency valve 2410 and the second emergency valve 2420 are controlled to supply the fluid and stop the supply of the fluid by changing the opening and closing state thereof over time, similar to the first valve 2310 and the second valve 2310 in the exemplary embodiment of FIG. 7. For example, the first emergency valve 2410 corresponds to the first valve 2310, and the second emergency valve 2420 corresponds to the second valve 2320.

FIG. 16 is a diagram schematically illustrating another exemplary embodiment of the fluid pipe coupled to the drying chamber of FIG. 1.

Referring to FIG. 16, the main valve 2300 and the emergency valve 2400 are each provided as a single valve. The main valve 2300 and the emergency valve 2400 are connected in series to each other in a single flow path, for example, the first pipe 2010. According to the exemplary embodiment, the main valve 2300 may be installed upstream from the emergency valve 2400 on the first pipe 2010. For example, the second pipe 2400 may not be provided.

In the exemplary embodiment of FIG. 16, when the main valve 2300 is in the normal state, the pulse processing operation S33 is performed by the main valve 2300 and the emergency valve 2400. For example, the main valve 2300 and the emergency valve 2400 are opened and closed similar to the first valve 2310 and the second valve 2320 of FIG. 7 and thus are controlled to supply the fluid and stop the supply of the fluid.

In the exemplary embodiment of FIG. 16, when the main valve 2300 is in the abnormal state, the main valve 2300 is maintained in the open state, and the emergency valve 2400 is controlled to pulse-supply the fluid and stop the supply of the fluid by repeating opening and closing.

FIG. 17 is a diagram schematically illustrating another exemplary embodiment of the fluid pipe coupled to the drying chamber of FIG. 1.

Referring to FIG. 17, the fluid pipe 2000 includes a first pipe 2010, a second pipe 2020, and a third pipe 2030. The main valve 2300 includes a first valve 2310 and a second valve 2320. The emergency valve 2400 includes a first emergency valve 2410 and a second emergency valve 2420. The first valve 2310 and the first emergency valve 2410 are installed in the first pipe 2010. The second valve 2320 is installed in the second pipe 2020. Further, the second emergency valve 2420 is installed in the third pipe 2030. The first emergency valve 2410 is installed downstream from the first valve 2310. The second pipe 2020 is branched from the first pipe 2010 at the first point 2011 upstream from the main valve 2300, and joins the first pipe 2010 at the second point 2012 that is downstream from the first valve 2310. The third pipe 2030 is branched from the first pipe 2010 at the third point 2013 which is a point between the second point 2012 and the first emergency valve 2410, and rejoins the first pipe 2010 at the fourth point 2014 that is downstream from the first emergency valve 2410.

In the exemplary embodiment of FIG. 17, when the main valve 2300 is in the normal state, one of the first emergency valve 2410 and the second emergency valve 2420 is opened and the other valve is closed. For example, in the normal state, the first emergency valve 2410 is maintained in the open state, and the second emergency valve 2420 is maintained in the closed state. Accordingly, the fluid does not pass through the third pipe 2030. The controller 30 controls the main valve 2400 to be opened and closed to perform the pulse processing operation S33. For example, the first valve 2310 and the second valve 2320 may be controlled in the same manner as the first valve 2310 and the second valve 2320 of FIG. 10.

In the exemplary embodiment of FIG. 17, when the main valve 2300 is in the abnormal state, a valve in which a leak occurs between the first valve 2310 and the second valve 2320 is closed, and the other valve is maintained in the open state. The controller 30 controls to open and close the emergency valve 2400 to perform the pulse processing operation S33. For example, the first emergency valve 2410 and the second emergency valve 2420 are controlled in the same manner as the first valve 2310 and the second valve 2320 of FIG. 10 which are connected in parallel with each other. For example, the first emergency valve 2410 may correspond to the first valve 2310 of FIG. 10 and the second emergency valve 2420 may correspond to the second valve 2320 of FIG. 10.

FIG. 18 is a diagram schematically illustrating another exemplary embodiment of the fluid pipe coupled to the drying chamber of FIG. 1.

Referring to FIG. 18, the fluid pipe 2000 includes a first pipe 2010 and a second pipe 2020. The main valve 2300 includes a first valve 2310 and a second valve 2320, and the emergency valve 2400 includes a first emergency valve 2410 and a second emergency valve 2420. The first valve 2310 and the first emergency valve 2410 are installed in the first pipe 2010, and the second valve 2320 and the second emergency valve 2420 are installed in the second pipe 2020. The first valve 2310 is installed upstream from the first emergency valve 2410 in the first pipe 2010. The second valve 2320 is installed upstream from the second emergency valve 2420 in the second pipe 2020. The second pipe 2020 is branched from the first pipe 2010 at the first point 2011 upstream from the first valve 2310, and joins the first pipe 2010 at the second point 2012 downstream from the first emergency valve 2410.

In the exemplary embodiment of FIG. 18, when the main valve 2300 is in the normal state, the first emergency valve 2410 and the second emergency valve 2420 are maintained in the open state. The controller 30 controls the first valve 2310 and the second valve 2320 to be opened and closed to perform the supplying operation S331 and the exhausting operation S332. For example, the first valve 2310 and the second valve 2320 connected in parallel to each other may be controlled in the same manner as the first valve 2310 and the second valve 2320 of FIG. 10.

In the exemplary embodiment of FIG. 18, when the main valve 2300 is in the abnormal state, the supplying operation S331 and the exhausting operation S332 are performed as follows. Hereinafter, the present invention will be described based on the case where a leak occurs in the first valve 2310 of the main valve 2300 as an example. In this case, the pulse processing operation S33 may be performed through the second valve 2320, or the pulse processing operation S33 may be performed through the second valve 2320 and the second emergency valve 2420.

When the pulse processing operation S33 is performed only through the second valve 2320, both the first valve 2310 and the first emergency valve 2410 are closed, and the second emergency valve 2420 is opened. Then, the second valve 2320 is opened or closed by the controller 30, and thus the pulse processing operation S33 is performed. When the pulse processing operation S33 is performed through the second valve 230 and the second emergency valve 2420, both the first valve 2310 and the first emergency valve 2410 are closed. Then, the second valve 2320 and the second emergency valve 2420 are opened or closed by the controller 30, and thus the pulse processing operation S33 is performed. In this case, the second valve 2320 and the second emergency valve 2420 may be controlled in the same manner as the first valve 2310 and the second valve 2320 of FIG. 7 connected in series with each other.

Hereinafter, various modified examples of the substrate processing apparatus according to the present invention will be described.

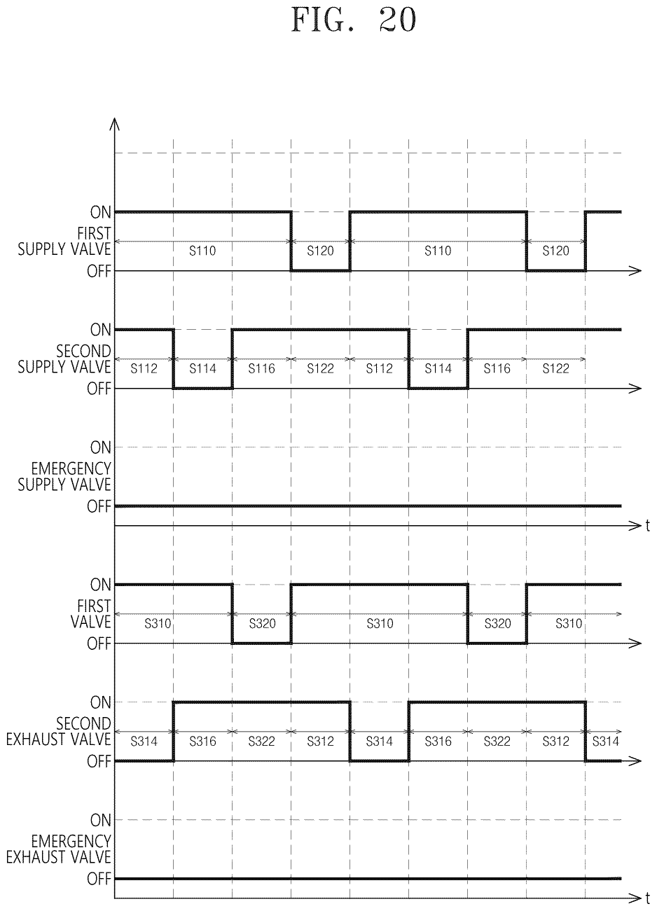

In the above-described exemplary embodiment of FIG. 8, it has been described that the second valve is closed once during the opening operation S110 of the first valve. However, this is illustrative and the present invention is not limited thereto. Referring to FIG. 20, while the opening operation S110 of the first valve is performed, an additional opening operation S117 of the second valve and an additional closing operation S118 of the second valve may be performed. Also, the additional opening operation S117 of the second valve and the additional closing operation S118 of the second valve may be repeated a plurality of times.

Similarly, the exemplary embodiment of FIG. 12 shows a change in the opening and closing state between the valves 2310 and 2320 connected in parallel, an additional opening operation of the second valve and an additional closing operation of the second valve may be further included between the opening operation S214 of the second valve and the second closing operation S216 of the second valve.

In the above exemplary embodiment, it has been described that the main valve 2300 and the emergency valve 2400 are installed only on the first downstream supply pipe 2120 between the first downstream supply pipe 2120 and the second downstream supply pipe 2140. However, the present invention is not limited thereto, and the structure in which the main valve 2300 and the emergency valve 2400 are installed may also be applied to the second downstream supply pipe 2140.

The above-described exemplary embodiments in which the main valve 2300 and the emergency valve 2400 are applied to the fluid pipe 2000 may be applied not only to the supply pipe 2100 but also to the discharge pipe 2200. That is, the above emergency valve structure may be applied only to the supply pipe 2100, only to the discharge pipe 2200, or both the supply pipe 2100 and the discharge pipe 2200. When the above valve structure is applied to both the supply pipe 2100 and the discharge pipe 2200, the pulse processing operation S33 may be performed so that the supply pipe 2100 and the discharge pipe 2200 are opened and closed together, or the supply pipe 2100 and the discharge pipe 2200 are opened and closed alternately. In this case, the pulse period in the supply pipe 2100 and the pulse period in the discharge pipe 2200 are the same.

FIG. 20 is a graph schematically illustrating an example of a process of processing a substrate using a substrate processing apparatus.

Here, the main valve 2300 installed in the supply pipe 2100 is referred to as a first supply valve and a second supply valve, and the emergency valve 2400 on the side of the supply pipe 2100 is referred to as an emergency supply valve. In addition, the main valve 2300 on the side of the discharge pipe 2200 is referred to as a first exhaust valve and a second exhaust valve, and the emergency valve 2400 on the side of the discharge pipe 2200 is referred to as an emergency exhaust valve. Each of the main valve 2300 and the emergency valve 2400 is provided in the structure of the exemplary embodiment of FIG. 7 in which the main valve 2300 and the emergency valve 2400 are connected in series to each other. In this case, each of the valves 2300 and 2400 may be provided as a normal narrows valve.

Referring to FIG. 20, in the normal state of each main valve 2300, the emergency supply valve and the emergency exhaust valve are maintained in the closed state. The pulse processing operation S33 is performed by each main valve 2300. Each main valve 2300 is opened and closed as illustrated in the graph of FIG. 8. In this case, the closing operation S314 of the second exhaust valve is performed simultaneously with the first opening operation S112 of the second supply valve. As a result, the discharge pipe 2200 is closed in the state where the first downstream supply pipe 2120 is open, and the discharge pipe 2200 is opened in the state where the first downstream supply pipe 2120 is closed, so that pulse-supply and pulse exhaust are performed opposite to each other.

Also, unlike the exemplary embodiment of FIG. 20, the first opening operation S112 of the second supply valve may be controlled to be performed together with the first opening operation S32 of the second exhaust valve. In this case, the first downstream supply pipe 2120 and the discharge pipe 2200 are opened and closed together, such that pulse-supply and pulse exhaust are performed in the same manner.

In the above exemplary embodiment, the fluid pipe 2000 has been described as being connected to the reservoir 1320. However, this is illustrative and the present invention is not limited thereto. The fluid pipe 2000 may be directly connected to a fluid supply source side supplying a fluid other than the reservoir 1320.

In the above exemplary embodiment, it has been described that the first supply port 1122 is provided to the lower body 1120 and the second supply port 1112 is provided to the upper body 1110. However, this is illustrative and the present invention is not limited thereto. For example, any one of the first supply port 1122 and the second supply port 1112 may be provided at a side of the housing 1100.

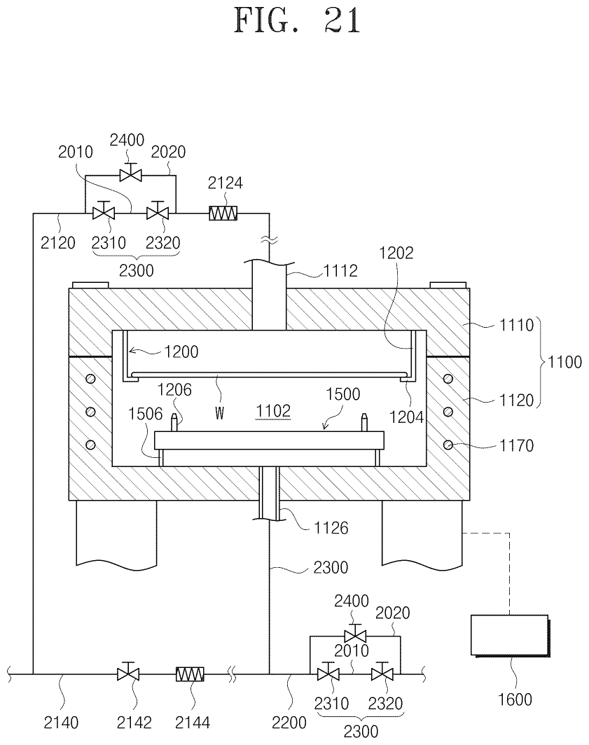

In the above exemplary embodiment, it has been described that the lower body 1120 is provided with the first supply port 1122 and the discharge port 1124. However, this is illustrative and the present invention is not limited thereto. For example, only one port may be provided in the lower body 1120. In this case, the supply of the fluid through the second downstream supply pipe 2140 and the discharge of the fluid through the discharge pipe 2200 may be performed through the single port 1126. For example, as illustrated in FIG. 21, the second downstream supply pipe 2140 and the discharge pipe 2200 may communicate with each other and may be provided in a structure connected to the single port 1126.

In the exemplary embodiments of FIGS. 4 and 10 described above, the emergency valve 2400 has been described as being provided as the normal close valve and the normal open valve. However, this is illustrative and does not limit the type of valve in each emergency valve 2400. For example, the emergency valve 2400 may be provided as a valve driven by a bellows method, a valve driven by a hydraulic or pneumatic actuator, a valve provided by a solenoid coil, or a valve using an electronic motor drive, regardless of the opening and closing state in a non-operation state.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
a housing having a treatment space for processing a substrate;
a support unit for supporting the substrate in the treatment space;
a fluid pipe which communicates with the treatment space and in which a fluid flows;
a main valve installed in the fluid pipe and opening and closing a passage through which the fluid flows in the fluid pipe;
an emergency valve installed in the fluid pipe and opening and closing the passage through which the fluid flows in the fluid pipe; and
a controller configured to control the main valve and the emergency valve,
wherein when the main valve is in a normal state, the controller controls the flow of fluid in the fluid pipe by operating the main valve between the main valve and the emergency valve, and when the main valve is in an abnormal state, the controller controls the flow of fluid in the fluid pipe by operating the emergency valve between the main valve and the emergency valve.

2. The apparatus of claim 1, wherein the fluid pipe includes:
a first pipe in which the main valve is installed; and
a second pipe in which the emergency valve is installed, and
the second pipe is branched from the first pipe at a first point that is upstream from the main valve and joins the first pipe at a second point that is downstream from the main valve.

3. The apparatus of claim 2, wherein each of the main valve and the emergency valve is a normal close valve.

4. The apparatus of claim 2, wherein while the fluid pipe is controlled to be opened and closed by any one of the main valve and the emergency valve, the other valve is maintained in a closed state.

5. The apparatus of claim 1, wherein the main valve and the emergency valve are arranged in series with each other.

6. The apparatus of claim 5, wherein each of the main valve and the emergency valve is a normal open valve.

7. The apparatus of claim 5, wherein while the fluid pipe is controlled to be opened and closed by any one of the main valve or the emergency valve, the other valve is maintained in an open state.

8. The apparatus of claim 1, wherein whether the main valve is in a normal state is determined based on whether a leak occurs in a pipe to which a driving pressure for driving the main valve is provided, whether a leak occurs in the main valve, or whether a leak occurs in the supply pipe.

9. The apparatus of claim 1, wherein the fluid pipe is a supply pipe that supplies a fluid to the treatment space.

10. The apparatus of claim 1, wherein the fluid pipe is a discharge pipe that discharges a fluid from the treatment space.

11. The apparatus of claim 1, further comprising:
a reservoir in which a fluid is stored,
wherein the fluid pipe includes:
a supply pipe for supplying a fluid to the treatment space; and
a discharge pipe for discharging a fluid from the treatment space,
the supply pipe includes:
an upstream supply pipe connected to the reservoir;
a first downstream supply pipe branched from the upstream supply pipe and connected to the housing; and
a second downstream supply pipe branched from the upstream supply pipe and connected to the housing, and
both the main valve and the emergency valve are installed only in the first downstream supply pipe between the first downstream supply pipe and the second downstream supply pipe.

12. The apparatus of claim 1, wherein the main valve and the emergency valve have the same structure.

13. The apparatus of claim 1, wherein the controller controls the apparatus to sequentially perform:
a loading operation of loading the substrate into the treatment space;
after the loading operation, a pressurizing operation of pressurizing the treatment space by supplying the fluid to the treatment space;
after the pressurizing operation, a pulse processing operation of pulse-supplying the fluid into the treatment space to process the substrate in the treatment space;
a depressurizing operation of depressurizing the treatment space by discharging the fluid from the treatment space; and
a discharging operation of discharging the substrate from the treatment space after the depressurizing operation, and
in the pulse processing operation, the controller controls the apparatus so that the fluid is supplied and the supply of the fluid is stopped by controlling the main valve.

14. The apparatus of claim 13, further comprising:
a reservoir in which a fluid is stored,
wherein the fluid pipe includes:
a supply pipe for supplying a fluid to the treatment space; and
a discharge pipe for discharging a fluid from the treatment space, and
the supply pipe includes:
an upstream supply pipe connected to the reservoir;
a first downstream supply pipe branched from the upstream supply pipe and connected to the housing; and
a second downstream supply pipe branched from the upstream supply pipe and connected to the housing, and
both the main valve and the emergency valve are installed only in the first downstream supply pipe between the first downstream supply pipe and the second downstream supply pipe,
the main valve includes:
a first valve; and
a second valve connected in series with the first valve,
the controller controls,
the fluid to be supplied to the treatment space through the second upstream supply pipe in the pressurizing operation,
the fluid to be pulse supplied to the treatment space through the first upstream supply pipe in the pulse processing operation, and
the first valve and the second valve to be opened and closed by opening and closing a passage of the fluid pipe supplying the fluid to the treatment space in the pulse processing operation,
the pulse processing operation includes:
an opening operation of a first valve in which the first valve is opened; and
a closing operation of the first valve in which the first valve is closed, and
the controller controls a first opening operation of the second valve in which the second valve is opened, a closing operation of the second valve in which the second valve is closed, and a second opening operation of the second valve in which the second valve is opened to be sequentially performed during the opening operation of the first valve.

15. An apparatus for processing a substrate, the apparatus comprising:
a housing having a treatment space for processing a substrate;
a support unit for supporting a substrate in the treatment space;
a fluid pipe which communicates with the treatment space and in which a fluid flows;
a main valve installed in the fluid pipe and opening and closing a passage through which the fluid flows in the fluid pipe; and
an emergency valve installed in the fluid pipe and opening and closing the passage through which the fluid flows in the fluid pipe.

16. The apparatus of claim 15, further comprising:
a controller for controlling the main valve and the emergency valve,
wherein the main valve and the emergency valve are arranged in series with each other,
each of the main valve and the emergency valve is a normal open valve,
the controller operates the main valve between the main valve and the emergency valve when the main valve is in a normal state to control the flow of the fluid in the fluid pipe, and controls the emergency valve to be maintained in an open state while the fluid pipe is controlled to be opened and closed by the main valve, and
the controller operates the emergency valve between the main valve and the emergency valve when the main valve is in an abnormal state to control the flow of the fluid in the fluid pipe, and controls the main valve to be maintained in an open state while the fluid pipe is controlled to be opened and closed by the emergency valve.

17. The apparatus of claim 16, wherein the controller includes:
a loading operation of loading the substrate into the treatment space;
after the loading operation, a processing operation of processing the substrate loaded into the treatment space with the fluid by supplying the fluid to the treatment space; and
after the processing operation, an unloading operation of unloading the substrate from the treatment space, and
the processing operation includes a supplying operation of pulse-supplying the fluid into the treatment space by controlling the main valve and the emergency valve,
in the supplying operation, the controller controls an opening operation of the main valve in which the main valve is opened and a closing operation of the main valve in which the main valve is closed to be sequentially performed, the closing operation of the main valve being performed immediately after the opening operation of the main valve, and
the controller controls a first closing operation of the emergency valve in which the emergency valve is closed, an opening operation of the emergency valve in which the emergency valve is opened, and a second closing operation of the emergency valve in which the emergency valve is closed to be sequentially performed during the closing operation of the main valve.

18. The apparatus of claim 15, further comprising:
a controller for controlling the main valve and the emergency valve,
wherein the main valve and the emergency valve are arranged in parallel with each other,
each of the main valve and the emergency valve is a normal open valve,
the controller operates the main valve between the main valve and the emergency valve when the main valve is in a normal state to control the flow of the fluid in the fluid pipe, and controls the emergency valve to be maintained in a closed state while the fluid pipe is controlled to be opened and closed by the main valve, and
the controller operates the emergency valve between the main valve and the emergency valve when the main valve is in an abnormal state to control the flow of the fluid in the fluid pipe, and controls the main valve to be maintained in a closed state while the fluid pipe is controlled to be opened and closed by the emergency valve.

19. The apparatus of claim 18, wherein the fluid pipe includes:
a first pipe in which the main valve is installed; and
a second pipe in which the emergency valve is installed, and
the second pipe is branched from the first pipe at a first point upstream from the main valve and joins the first pipe at a second point downstream from the main valve,
the main valve includes a first valve and a second valve that open and close passages through which the fluid flows in the first pipe, respectively, between the first point and the second point,
the controller includes:
a loading operation of loading the substrate into the treatment space;
after the loading operation, a processing operation of processing the substrate loaded into the treatment space with the fluid by supplying the fluid to the treatment space; and
after the processing operation, an unloading operation of unloading the substrate from the treatment space, and
the processing operation includes a supplying operation of pulse-supplying the fluid into the treatment space by controlling the main valve and the emergency valve,
in the supplying operation, the controller controls an opening operation of the first valve in which the first valve is opened, and a closing operation of the first valve in which the first valve is closed to be sequentially performed, the closing operation of the first valve being performed immediately after the opening operation of the first valve, and
the controller controls a first closing operation of the second valve in which the second valve is closed, an opening operation of the second valve in which the second valve is opened, and a second closing operation of the second valve in which the second valve is closed to be sequentially performed during the closing operation of the first valve.

20. An apparatus for processing a substrate, the apparatus comprising:
a housing having a treatment space for processing a substrate;
a support unit for supporting a substrate in the treatment space;
a fluid pipe which communicates with the treatment space and in which a supercritical fluid flows;
a main valve installed in the fluid pipe and opening and closing a passage through which the supercritical fluid flows in the fluid pipe;
an emergency valve installed in the fluid pipe and opening and closing the passage through which the supercritical fluid flows; and
a controller for controlling the main valve and the emergency valve,
wherein the fluid pipe includes:
a first pipe in which the main valve is installed; and
a second pipe in which the emergency valve is installed, and
the second pipe is branched from the first pipe at a first point upstream from the main valve and joins the first pipe at a second point downstream from the main valve,
the main valve includes a first valve and a second valve that open and close passages through which the fluid flows in the first pipe, respectively, between the first point and the second point,
the first valve and the second valve are arranged in series,
when the main valve is in a normal state, the controller operates the main valve between the main valve and the emergency valve to control the flow of fluid in the fluid pipe, and when the main valve is in an abnormal state, the controller operates the emergency valve between the main valve and the emergency valve to control the flow of the fluid in the fluid pipe,
when the main valve is in the normal state, the controller includes an opening of the first valve in which the first valve is opened; and a closing operation of the first valve in which the first valve is closed immediately after the opening operation of the first valve, and
the controller controls the main valve so that a first opening operation of the second valve in which the second valve is opened, a closing operation of the second valve in which the second valve is closed, and a second opening operation of the second valve in which the second valve is opened are sequentially performed during the opening operation of the first valve.
